(19) United States
(12) Patent Application Publication
(10) Pub. No.: US 2025/0384947 A1
(43) Pub. Date: Dec. 18, 2025

(54) CHARGE LOSS WEAK DIE IDENTIFICATION

(71) Applicant: Micron Technology, Inc., Boise, ID (US)

(72) Inventors: Zhongguang Xu, San Jose, CA (US); Murong Lang, San Jose, CA (US); Hanping Chen, San Jose, CA (US); Zhenming Zhou, San Jose, CA (US)

(21) Appl. No.: 19/181,061

(22) Filed: Apr. 16, 2025

Related U.S. Application Data
(60) Provisional application No. 63/643,272, filed on May 6, 2024.

(51) Int. Cl. G11C 29/50

(52) U.S. Cl. CPC G11C 29/50004

(57) ABSTRACT

Methods, systems, and devices for charge loss weak die identification are described. The described techniques provide for a memory system to avoid sampling, during block family (BF) scans, blocks of memory cells associated with memory dies that are classified as read disturb charge loss (RDCL) weak dies. The memory system may identify a memory die as being an RDCL weak die based on a threshold quantity of blocks associated with the memory die experiencing relatively high charge loss. If the quantity satisfies a threshold value, the memory system may classify the memory die as an RDCL weak die and the memory system may refrain from selecting blocks from a BF that are associated with a memory die classified as an RDCL weak die.

### CROSS REFERENCE

The present application for patent claims priority to U.S. Patent Application No. 63/643,272 by Xu et al., entitled “CHARGE LOSS WEAK DIE IDENTIFICATION,” filed May 6, 2024, which is assigned to the assignee hereof, and which is expressly incorporated by reference in its entirety herein.

### TECHNICAL FIELD

The following relates to one or more systems for memory, including charge loss weak die identification.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports charge loss weak die identification in accordance with examples as disclosed herein.

FIG. 2 shows an example of a process flow that supports charge loss weak die identification in accordance with examples as disclosed herein.

FIG. 3 shows an example of a process flow that supports charge loss weak die identification in accordance with examples as disclosed herein.

FIG. 4 shows a block diagram of a memory system that supports charge loss weak die identification in accordance with examples as disclosed herein.

FIGS. 5 and 6 show flowcharts illustrating a method or methods that support charge loss weak die identification in accordance with examples as disclosed herein.

### DETAILED DESCRIPTION

Some memory systems may include arrays of memory cells configured to store information. For example, data may be programmed to (e.g., written to) or obtained from (e.g., read from) the memory cells to support procedures or operations of the associated memory system. The memory system may include such arrays of memory cells in one or more memory dies, where each memory die may include one or more blocks of memory cells. In some examples, the memory system may perform testing procedures to identify a suitability of memory cells to store data. For example, the memory system may support block family (BF) error avoidance (BFEA) procedures, which may include a BF scan. As described herein, a BF may refer to a set of multiple blocks of memory cells where each of the blocks in the BF may be associated with a respective memory die of the memory system. As part of the BF scan, the memory system may sample a single block from a BF by applying a voltage (e.g., a read voltage) to the memory cells of the block.

The memory system may identify a voltage characteristic of the block based on applying the voltage, such as a voltage differential experienced by the block during the sampling. In some cases, if the voltage characteristic satisfies a threshold value (e.g., is relatively high, is above a threshold value), the memory system may categorize the block or a memory die associated with the block as unsuitable for subsequent operations (e.g., the block or die may be considered defective). For example, if the voltage differential (e.g., a read disturb charge loss (RDCL)) of the block satisfies the threshold value, the memory system may include (e.g., categorize) the memory die associated with the block in a particular BFEA bin, which may indicate that the memory die is unsuitable for subsequent operations (e.g., based on the higher index of the BFEA bin) and, in some cases, may result in retirement of the memory die.

In some examples, however, such voltage differentials may not be indicative of a faulty or otherwise defective memory die. For example, a metal process associated with manufacturing of the memory cells may result in the memory cells experiencing relatively high charge loss when applying a voltage (e.g., at a higher rate than one or more other memory dies), which may be exacerbated when sampling a block at relatively high temperatures. In such examples, the voltage differential may not be indicative of a defect of the block of memory cells (e.g., the error may be transient in nature based on physical properties of the memory cells). However, the memory system may continue to include memory dies in a particular BFEA bin during BF scans when sampling blocks that experience relatively high charge loss, which may result in memory dies being retired at an undesirably high rate, thereby reducing performance of the memory system (e.g., because such dies may otherwise work properly for maintaining information).

A memory system configured to reduce a rate at which memory dies are retired or otherwise indicated to be unsuitable for maintaining information when performing BF scans is described herein. In accordance with examples as disclosed herein, the memory system may be configured to avoid sampling blocks of memory cells (e.g., during BF scans) associated with memory dies that are classified as RDCL weak dies. An RDCL weak die may refer to a memory die that includes blocks of memory cells which experience charge loss at a relatively high rate (e.g., at a rate above a threshold voltage differential) when applying a voltage. The memory system may identify a memory die as being an RDCL weak die based on a threshold quantity of blocks associated with the memory die experiencing the relatively high charge loss. For example, during a BF scan, the memory system may sample a block associated with a first memory die and may identify that the voltage differential of the block satisfies a first threshold value.

The memory system may adjust (e.g., increment) a counter associated with the first memory die (e.g., indicating a quantity of blocks associated with the memory die that experience the threshold voltage differential) and may compare the value of the counter with a second threshold value. If the value of the counter satisfies the second threshold value, the memory system may classify the memory die as an RDCL weak die by storing an indication that the first memory die experiences charge loss at a higher rate than one or more other memory dies. During subsequent BF scans, the memory system may refrain from selecting blocks from a BF that are associated with a memory die classified as an RDCL weak die. For example, the memory system may sample a block associated with a second memory die (e.g., not classified as an RDCL weak die) during a subsequent BF scan. In some examples, such techniques may be extended to support classifying blocks as RDCL weak blocks and avoiding RDCL weak blocks during BF scans (e.g., in certain implementations, such as a mobile implementation). Such techniques may support the memory system performing BFEA procedures while reducing a trigger rate for block retirement, which may improve subsequent operations or procedures of the memory system.

In addition to applicability in memory systems as described herein, techniques for charge loss weak die identification may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing a trigger rate for block retirement, which may decrease latency times and improve processing capabilities by increasing the quantity of available blocks during standard operations, among other benefits.

In addition to applicability in memory systems as described herein, techniques for charge loss weak die identification may be generally implemented to support edge computing applications. Edge computing is a distributed computing paradigm that brings computation and data storage closer to the sources of data than traditional cloud services. As the use of edge computing to provide computing, storage, and networking services at locations that are geographically closer to end users increases, many devices and systems may benefit from improved processing, performance, and storage at edge devices. For example, increasing memory density, capacity, and processing power of edge devices may decrease a reliance on the devices to remote computing or devices, which may otherwise increase latency of operations performed at the devices. Implementing the techniques described herein may support edge computing techniques by reducing a trigger rate for block retirement, which may decrease latency times and improve processing capabilities by increasing the quantity of available blocks during standard operations, among other benefits.

Features of the disclosure are illustrated and described in the context of systems, devices, and circuits. Features of the disclosure are further illustrated and described in the context of process flows and flowcharts.

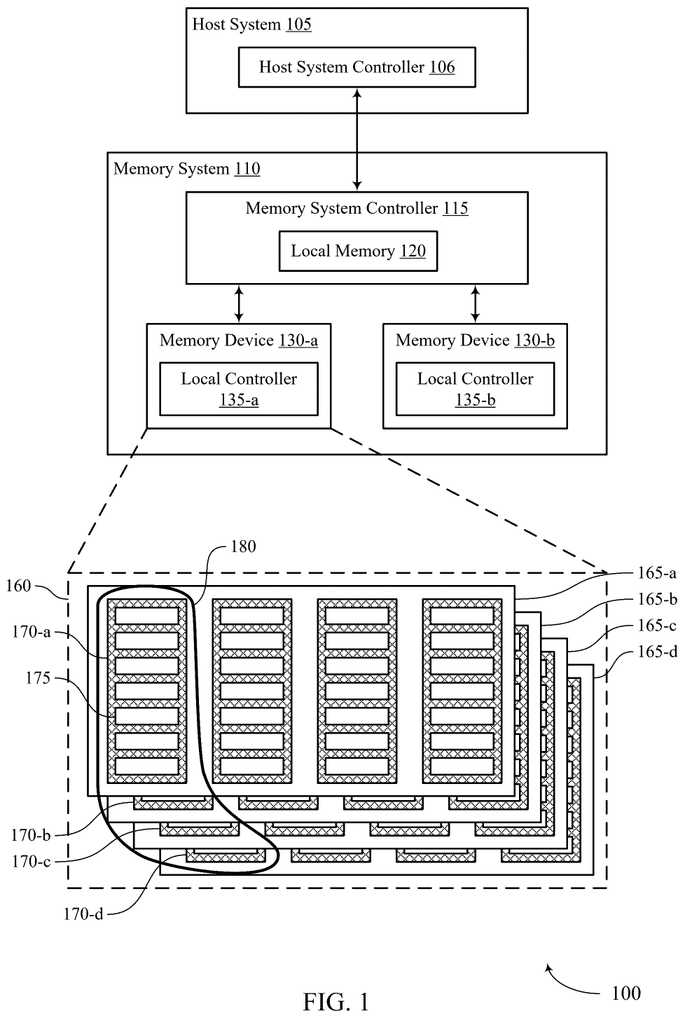

FIG. 1 shows an example of a system 100 that supports charge loss weak die identification in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some examples of the system 100, a memory system 110 may be configured to reduce a rate at which dies 160 are retired or otherwise indicated to be unsuitable for maintaining information when performing BF scans. For example, the memory system 110 may apply a voltage to a block 170 as part of a BF scan and may identify a voltage characteristic of the block 170, such as a voltage differential experienced by the block 170. In some cases, the memory system 110 may identify whether the block 170 experiences charge loss at a higher rate than one or more other blocks 170 based on applying the voltage. If the block 170 does experience a threshold charge loss in response to a voltage being applied, the memory system 110 may categorize the block 170, a die 160 associated with the block 170, or both as unsuitable for operation, which may, in some examples, lead to retirement of the block 170 or the die 160. However, such charge loss may be due to physical parameters of the block 170, such as a metal process associated with manufacturing the block 170 and a temperature of the block 170, and may not be indicative of a block 170 that is inoperative (e.g., the error may be transient). To avoid triggering block retirement in response to a block 170 experiencing a threshold charge loss, the memory system 110 may categorize such blocks 170 and associated dies 160 as RDCL weak, and the memory system 110 may avoid selecting RDCL weak dies 160 and blocks 170 during subsequent BF scans. Such techniques may reduce a trigger rate of block retirement, which may improve performance of the memory system 110 may increasing a quantity of available blocks 170 for performing operations, among other advantages.

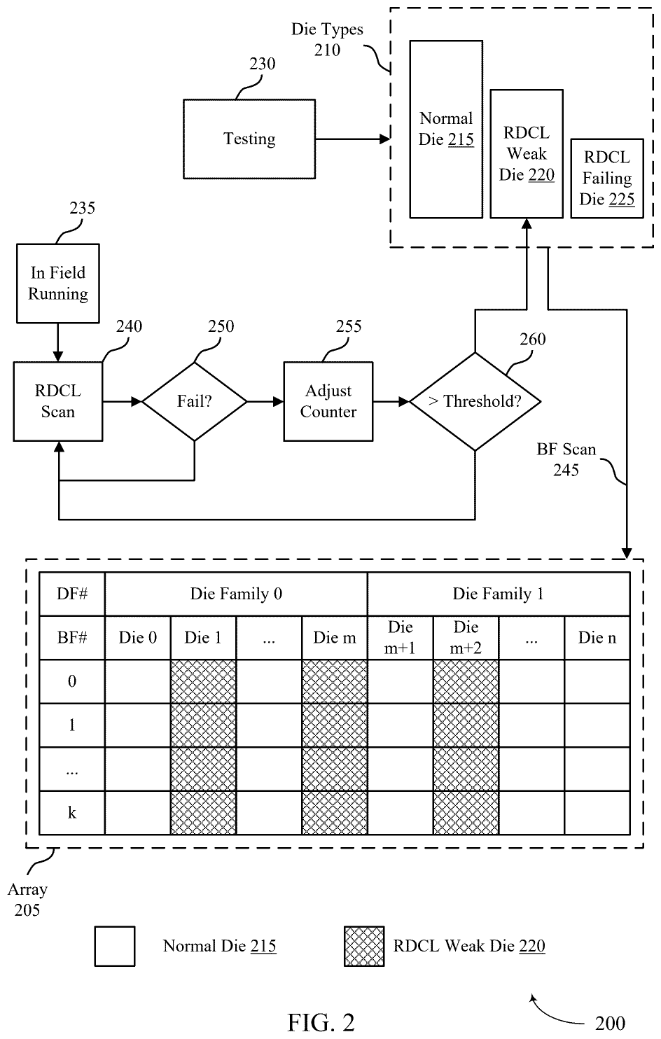

FIG. 2 shows an example of a process flow 200 that supports charge loss weak die identification in accordance with examples as disclosed herein. The process flow 200 may implement, or be implemented by, one or more aspects of the system 100. For example, the process flow 200 may show examples of operations performed by a memory system, such as a memory system 110 described with reference to FIG. 1. Such operations may be associated with the memory system scanning an array 205, which may include one or more blocks of memory cells and one or more memory dies including respective blocks of memory cells, which may be examples of corresponding aspects described with reference to FIG. 1. In some cases, the process flow 200 may support the memory system classifying memory dies into one or more die types 210, which may indicate whether a memory die is a normal die 215, an RDCL weak die 220, or an RDCL failing die 225. As described herein, the one or more die types 210 may be configured as BFEA bins (e.g., where an index of the BFEA bin may correspond to an operational status of a memory die) or may be configured as another logical construct for categorizing information, such as a table configured for storing die classifications during BF scans.

At 230, a testing operation may be performed on a set of one or more memory dies of a memory system. In some cases, testing circuitry associated with the memory system may facilitate the testing operation. For example, the testing circuitry may be external to the memory system and may be coupled with (e.g., temporarily coupled with) the memory system to support performing the testing operation, which may be an example of an initial scan performed on the one or more memory dies to identify characteristics of the memory dies (e.g., a probe test). For example, the testing operation may include the testing circuitry identifying a die type 210 of each memory die (e.g., an initial die type 210). In some cases, the testing operation may include or be an example of an RDCL screen test. As part of the RDCL screen test, the testing circuitry may apply a voltage to each of the one or more memory dies (e.g., one or more blocks associated with each memory die) and may identify one or more characteristics of each memory die based on applying the voltage. For example, if a first memory die experiences a voltage differential (e.g., in response to applying the voltage) that is below a first threshold value, the testing circuitry may identify that a die type 210 of the first memory die is a normal die 215.

In another example, if a second memory die experiences a voltage differential that is above the first threshold value and below a second threshold value, the testing circuitry may identify that a die type 210 of the second memory die is an RDCL weak die 220. In another example, if a third memory die experiences a voltage differential that is above the second threshold value, the testing circuitry may identify that a die type 210 of the third memory die is an RDCL failing die 225 (e.g., a memory die that may be prone to significant error and should not be used for subsequent operations, which may be screened out during the testing operation at 230).

In some examples, however, the testing operation at 230 may fail to identify a die type 210 for each memory die. For example, in some cases, a temperature associated with a memory die may affect the voltage characteristics of the memory die when applying a voltage to a block associated with the memory die. As such, during in-field running 235 (e.g., when the memory system is in an operational state), the memory system may sample blocks of memory cells to identify characteristics of the memory dies (e.g., identifying the characteristics dynamically in view of operational conditions, such as temperature).

At 240, the memory system may perform an RDCL scan, which may be an example of an operation performed during the in-field running 235. In some cases, the RDCL scan may include the memory system sampling a BF to identify voltage characteristics of the block. For example, during the RDCL scan, the memory system may perform a BF scan 245, which may include the memory system selecting a block of memory cells from a first BF (e.g., BF #0 of the array 205) and applying a voltage to the selected block of memory cells. During the BF scan 245, if the memory system identifies a block of memory cells that experiences the threshold voltage differential, the memory system may categorize a memory die associated with the block of memory cells as a RDCL failing die 225 or otherwise indicate that the memory die should be retired from use during subsequent operations (e.g., due to identifying the threshold voltage differential). However, such a voltage differential may not be indicative of a failing or otherwise inoperative memory die, and as such classifying the memory die as an RDCL weak die 220 may reduce a performance of the memory system. For example, due to the metal process associated with the manufacturing of the memory die, an error associated with the voltage differential of a block of memory cells may be relatively transient in nature, such as when the block is sampled at a relatively high temperature.

Techniques described herein may support the memory system avoiding sampling memory dies categorized as RDCL weak dies 220 when performing BF scans 245 during the in-field running 235. As an example, after the testing operation at 230, a die 0 of a die family 0 of the array 205 may be categorized as a normal die 215, a die 1 of the die family 0 may be categorized as a RDCL weak die 220, and a die m of the die family 0 may be categorized as a RDCL weak die 220. In such examples, the memory system may be configured to avoid selecting, for a BF scan 245, blocks of memory cells associated with the die 1 and the die m (e.g., due to these dies being binned as RDCL weak dies 220). The memory system may similarly avoid selecting RDCL weak dies 220 included in other die families, such as a die m+2 of the die family 1, and so on.

Additionally, the described techniques may support the memory system categorizing, during the in-field running 235 (e.g., dynamically), memory dies that experience a threshold voltage differential as RDCL weak dies 220 (e.g., instead of indicating the memory dies should be retired), which may support the memory system avoiding blocks associated with such memory dies during subsequent BF scans 245 while reducing a trigger rate of die retirement. For example, during an RDCL scan at 240, the memory system may select a block of a normal die 215 for a BF scan 245 (e.g., a block associated with the die 0 due to avoiding the RDCL weak dies 220). At 250, the memory system may identify whether the selected block of memory cells experiences the threshold voltage differential in response to applying a voltage (e.g., determining whether the block is failing). For example, if the memory system applies the voltage to the block and identifies that the voltage differential of the block does not satisfy the threshold voltage differential (e.g., a first threshold value), the memory system may return initiate a subsequent RDCL scan at 240. In some other examples, in response to the block not failing, the memory system may return to the in-field running 235 (e.g., to perform different operations or procedures). Alternatively, if the memory system applies the voltage to the block and identifies that the voltage differential of the block satisfies the first threshold value, the memory system may proceed to 255.

At 255, the memory system may adjust a counter associated with a memory die that includes the selected block of memory cells. For example, if the memory system identifies that a block of the die 0 experiences a voltage differential that satisfies the first threshold value, the memory system may increment a counter associated with the die 0 (e.g., Fail_Count_RDCL+1). The counter may indicate a quantity of blocks included in the memory die that have been identified to experience charge loss at a higher rate than blocks of one or more other memory dies (e.g., a quantity of failing blocks in the memory die).

At 260, the memory system may compare the value of the counter associated with the memory die with a threshold value (e.g., a second threshold value). In some cases, the memory system may identify that the value of the counter fails to satisfy the second threshold value, and the memory system may return to perform a subsequent RDCL scan at 240 or may return to in-field running 235 (e.g., to facilitate other operations or procedures). In some other examples, the memory system may identify that the value of the counter satisfies the second threshold value, and the memory system may store an indication that the memory die experiences charge loss at a higher rate than one or more other memory dies.

For example, the memory system may classify the die 0 as an RDCL weak die 220 (e.g., despite the die 0 being classified as a normal die 215 during the testing operation at 230) and may avoid selecting blocks associated with the die 0 during subsequent BF scans 245. Additionally, or alternatively, the memory system may determine whether to store the indication that the memory die experiences the charge loss at the higher rate than other memory dies based on a quantity of memory dies of the memory system that are indicated to experience the charge loss at the higher rate (e.g., a quantity of memory dies classified as RDCL weak dies 220). For example, if the memory system identifies that the quantity of memory dies classified as RDCL weak dies 220 satisfies a threshold quantity of memory dies (referred to as a third threshold, which may correspond to a percentage of memory dies of the memory system, such as 20%), the memory system may refrain from storing the indication despite the value of the counter satisfying the second threshold value.

In some examples, the memory system may apply such techniques at the block level (e.g., in a mobile implementation). For example, each block of the memory system may be associated with a respective counter and the memory system may maintain values of each respective counter to identify whether the block should be classified as normal, RDCL weak, or RDCL failing. For example, the memory system may classify a first block of memory cells as an RDCL weak block (e.g., due to the counter associated with block satisfying a threshold value after identifying the block experiences the threshold voltage differential) and the memory system may avoid selecting the block for a subsequent BF scan 245.

Such techniques may support the memory system avoiding selection of blocks associated with RDCL weak dies 220 (or blocks classified as RDCL weak) during BF scans 245 and updating die classifications during in-field running, which may reduce a trigger rate of die or block retirement and improve overall performance of the memory system.

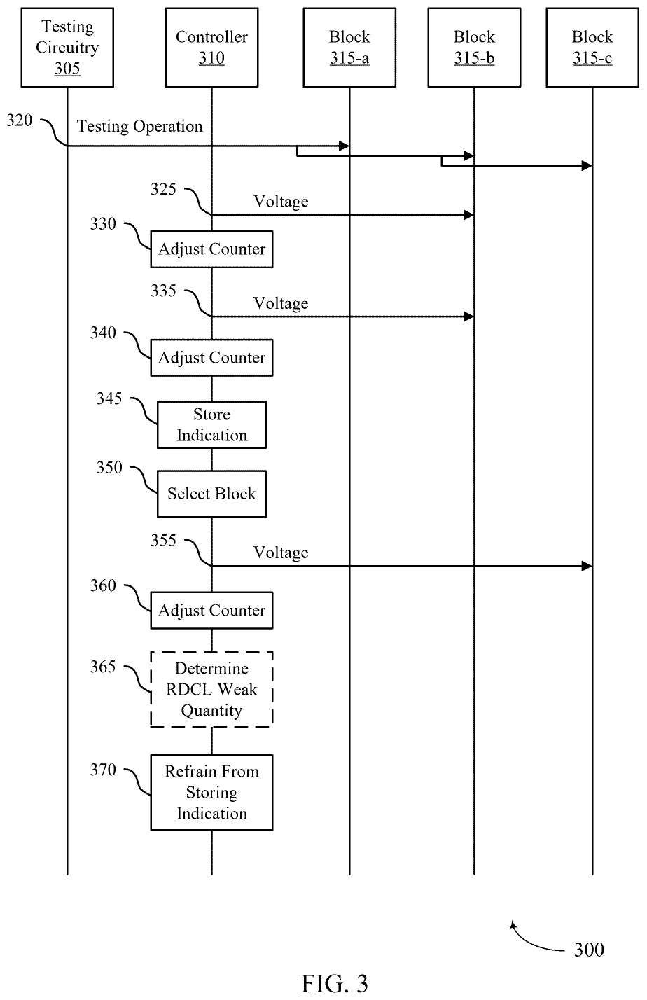

FIG. 3 shows an example of a process flow 300 that supports charge loss weak die identification in accordance with examples as disclosed herein. The process flow 300 may implement, or be implemented by, one or more aspects of the system 100 and the process flow 200. For example, the process flow 300 may include signaling and operations performed by aspects of a memory system, such as testing circuitry 305, a controller 310, and one or more blocks 315 (e.g., a block 315-a, a block 315-b, and a block 315-c), which may be examples of corresponding devices and aspects described with reference to FIGS. 1 and 2. In some cases, the process flow 300 may support the memory system avoiding blocks and dies classified as RDCL weak during BF scans, which may reduce a trigger rate of block retirement by the memory system. Alternative examples of the following may be implemented, where some processes are performed in a different order than described or are not performed. In some cases, processes may include additional features not mentioned below, or further processes may be added.

At 320, the testing circuitry may perform a testing operation on the one or more blocks 315 of the memory system. In some examples, the testing circuitry may be an example of circuitry temporarily coupled with the memory system and configured to perform a probe test to identify characteristics of blocks and memory dies of the memory system. The probe test may include the testing circuitry applying a voltage (e.g., a read voltage, a probe voltage, or another testing voltage) to the blocks 315, identifying voltage characteristics of the blocks 315 and one or more dies associated with the blocks 315, and classifying the blocks 315 and dies according to the voltage characteristic. For example, the testing circuitry may apply the voltage to the block 315-a and may identify that the block 315-a experiences a charge loss that satisfies a threshold value (e.g., indicating the block 315-a experiences charge loss at a higher rate than one or more other blocks 315).

Based on the charge loss of the block 315-a satisfying the threshold value, the testing circuitry may classify (e.g., characterize, bin) the block 315-a and/or a first memory die associated with the block 315-a as RDCL weak or RDCL failing (e.g., the block 315-a may be screened out as part of the probe test). Additionally, or alternatively, the testing circuitry may apply the voltage to the block 315-b and the block 315-c as part of the probe test. For example, the testing circuitry may identify that the block 315-b and the block 315-c experience a charge loss that does not satisfy the threshold value. In such examples, the testing circuitry may classify the block 315-b and/or a second memory die associated with the block 315-b as normal and may classify the block 315-c and/or a third memory die associated with the block 315-c as normal.

At 325, the controller 310 may apply a voltage (e.g., a first read voltage) to the block 315-b (e.g., a first block of memory cells associated with a first memory die). In some cases, applying the voltage may be part of a BF scan and the controller 310 may determine a voltage characteristic (e.g., charge loss) associated with the block 315-b based on applying the voltage. For example, the controller may determine that the voltage characteristic of the block 315-b satisfies a first threshold value.

At 330, the controller 310 may adjust a counter associated with the block 315-b or the first memory die associated with the block 315-b. For example, based on the voltage characteristic of the block 315-b satisfying the first threshold value, the controller 310 may increment the counter. In some cases, the counter may be associated with the first memory die and may indicate a quantity of blocks 315 of the first memory die that experience charge loss at a higher rate than blocks 315 of one or more other memory dies. Alternatively, the counter may be associated with the block 315-b and may indicate a quantity of times the block 315-b has experience charge loss at a higher rate than one or more other blocks 315-b. In some cases, the controller 310 may determine whether the value of the counter satisfies a second threshold value based on adjusting the value of the counter. For example, the controller 310 may determine that the value of the counter does not satisfy the second threshold value and may refrain from storing an indication that the first memory die or the block 315-b experience the charge loss at the higher rate than one or more other memory dies or blocks 315.

At 335, the controller 310 may apply a voltage (e.g., a second read voltage) to the block 315-b, which may be part of a second BF scan. In some cases, the block 315-b may be an example of a second block of memory cells associated with the first memory die (e.g., in a die-level implementation) or the block 315-b may be the same block of memory cells sampled at 325 (e.g., in a block-level implementation). In some cases, the controller 310 may identify, based on applying the voltage, that the voltage characteristic the block 315-b satisfies the first threshold value.

At 340, the controller 310 may adjust (e.g., increment) the value of the counter associated with the first memory die or associated with the block 315-b based on determining that the voltage characteristic of the second block satisfies the first threshold value. In some examples, the controller 310 may determine that the value of the counter satisfies the second threshold value based on adjusting the value of the counter.

At 345, the controller 310 may store an indication that the first memory die experiences the charge loss at the higher rate than one or more other memory dies based on the value of the counter satisfying the second threshold value. Alternatively, the controller 310 may store an indication that the first block experiences the charge loss at a higher rate than one or more other blocks based on the value of the counter satisfying the second threshold value. In some examples, storing the indication may be an example of the memory system classifying the first memory die as an RDCL weak die or the first block as an RDCL weak block.

At 350, the controller 310 may select a block of memory cells from a set of multiple blocks of memory cells, such as a block from a BF for a subsequent BF scan. In some cases, the controller 310 may refrain from selecting a third block of memory cells associated with the first memory die based on storing the indication that the first memory die experiences the charge loss at the higher rate than the one or more other memory dies. For example, the controller 310 may select a fourth block of memory cells that is associated with a second memory die based on the second memory die not experiencing the charge loss at the higher rate than the one or more other memory dies (e.g., no indication is stored for the second memory die). Alternatively, the controller 310 may refrain from selecting the first block of memory cells based on storing the indication that the first block experiences the charge loss at the higher rate than the one or more other blocks of memory cells, and may select a second block of memory cells based on the second block not experiencing the charge loss at the higher rate than the first block of memory cells.

At 355, the controller 310 may apply a voltage (e.g., as part of the subsequent BF scan) to the block 315-c, which may be an example of the block selected at 350. For example, the block 315-c may be associated with a second memory die different from the first memory die or may be a block different from the first block of memory cells. In some cases, the controller 310 may determine that the voltage characteristic of the block 315-c satisfies the first threshold value.

At 360, the controller 310 may adjust a value of a counter associated with the block 315-c or associated with the second memory die associated with the block 315-c. In some examples, the controller 310 may determine whether the value of the counter satisfies the second threshold value based on adjusting the value of the counter.

At 365, the controller 310 may determine a quantity of memory dies of the memory system that experience the charge loss at the higher rate than one or more other memory dies. Alternatively, the quantity may correspond to a quantity of blocks of the memory system that experience the charge loss at the higher rate than one or more other blocks. In some cases, the controller 310 may determine whether the quantity satisfies a third threshold value (e.g., a percentage of RDCL weak dies or blocks, such as 20%).

At 370, the controller 310 may refrain from storing a second indication that the second memory die or the block 315-c experiences the charge loss at the higher rate than the one or more other memory dies or blocks. For example, the controller 310 may refrain from storing the second indication based on the value of the counter failing to satisfy the second threshold value. Additionally, or alternatively, the controller 310 may refrain from storing the second indication based on the quantity of RDCL weak dies or blocks satisfying the third threshold value.

Such techniques may support the memory system avoiding selection of blocks 315 associated with RDCL weak dies (or blocks 315 classified as RDCL weak blocks) during BF scans and updating die classifications during in-field running, which may reduce a trigger rate of die or block retirement and improve overall performance of the memory system.

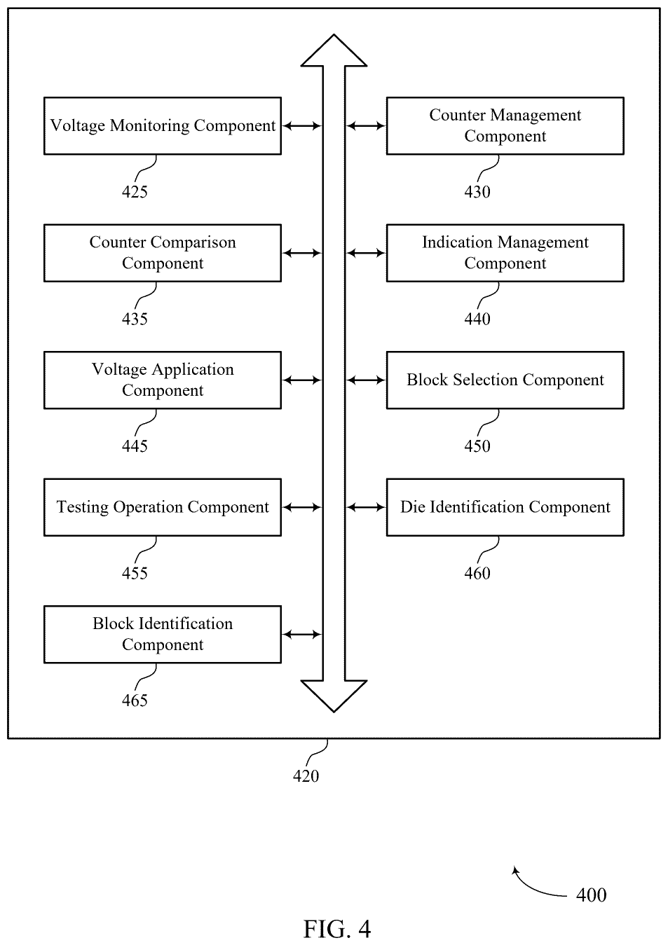

FIG. 4 shows a block diagram 400 of a memory system 420 that supports charge loss weak die identification in accordance with examples as disclosed herein. The memory system 420 may be an example of aspects of a memory system as described with reference to FIGS. 1 through 3. The memory system 420, or various components thereof, may be an example of means for performing various aspects of charge loss weak die identification as described herein. For example, the memory system 420 may include a voltage monitoring component 425, a counter management component 430, a counter comparison component 435, an indication management component 440, a voltage application component 445, a block selection component 450, a testing operation component 455, a die identification component 460, a block identification component 465, or any combination thereof. Each of these components, or components of subcomponents thereof (e.g., one or more processors, one or more memories), may communicate, directly or indirectly, with one another (e.g., via one or more buses).

The voltage monitoring component 425 may be configured as or otherwise support a means for determining that a voltage characteristic of a first block of memory cells satisfies a first threshold value, where the first block of memory cells is associated with a first memory die of the memory system. The counter management component 430 may be configured as or otherwise support a means for adjusting a value of a counter associated with the first memory die based at least in part on determining that the voltage characteristic of the first block satisfies the first threshold value. The counter comparison component 435 may be configured as or otherwise support a means for determining whether the value of the counter satisfies a second threshold value based at least in part on adjusting the value of the counter. The indication management component 440 may be configured as or otherwise support a means for storing an indication that the first memory die experiences charge loss at a higher rate than one or more other memory dies based at least in part on the value of the counter satisfying the second threshold value.

In some examples, the voltage application component 445 may be configured as or otherwise support a means for applying a first read voltage to the first block of memory cells, where the voltage characteristic includes a voltage differential of the first block of memory cells based at least in part on applying the first read voltage to the first block of memory cells.

In some examples, the voltage monitoring component 425 may be configured as or otherwise support a means for determining, prior to determining that the voltage characteristic of the first block of memory cells satisfies the first threshold value, that the voltage characteristic of a second block of memory cells satisfies the first threshold value, where the second block of memory cells is associated with the first memory die. In some examples, the counter management component 430 may be configured as or otherwise support a means for adjusting the value of the counter associated with the first memory die based at least in part on determining that the voltage characteristic of the second block satisfies the first threshold value. In some examples, the counter comparison component 435 may be configured as or otherwise support a means for determining whether the value of the counter satisfies a second threshold value based at least in part on adjusting the value of the counter. In some examples, the indication management component 440 may be configured as or otherwise support a means for refraining from storing the indication that the first memory die experiences the charge loss at the higher rate than the one or more other memory dies based at least in part on the value of the counter failing to satisfy the second threshold value.

In some examples, the block selection component 450 may be configured as or otherwise support a means for selecting a block of memory cells from a plurality of blocks of memory cells. In some examples, to select the block of memory cells, the block selection component 450 may be configured as or otherwise support a means for refraining from selecting a third block of memory cells of the plurality of blocks of memory cells that is associated with the first memory die based at least in part on storing the indication that the first memory die experiences the charge loss at the higher rate than the one or more other memory dies. In some examples, the block selection component 450 may be configured as or otherwise support a means for selecting a fourth block of memory cells of the plurality of blocks of memory cells that is associated with a second memory die based at least in part on the second memory die not experiencing the charge loss at the higher rate than the one or more other memory dies.

In some examples, the voltage monitoring component 425 may be configured as or otherwise support a means for determining that the voltage characteristic of a fourth block of memory cells satisfies the first threshold value, where the fourth block of memory cells is associated with a second memory die of the memory system. In some examples, the counter management component 430 may be configured as or otherwise support a means for adjusting a value of a second counter associated with the second memory die based at least in part on determining that the voltage characteristic of the fourth block satisfies the first threshold value. In some examples, the indication management component 440 may be configured as or otherwise support a means for refraining from storing a second indication that the second memory die experiences the charge loss at the higher rate than the one or more other memory dies based at least in part on the value of the second counter failing to satisfy the second threshold value.

In some examples, the voltage monitoring component 425 may be configured as or otherwise support a means for determining that the voltage characteristic of a fifth block of memory cells satisfies the first threshold value, where the fifth block of memory cells is associated with the second memory die. In some examples, the counter management component 430 may be configured as or otherwise support a means for adjusting the value of the second counter based at least in part on determining that the voltage characteristic of the fifth block satisfies the first threshold value. In some examples, the counter comparison component 435 may be configured as or otherwise support a means for determining that the value of the second counter satisfies the second threshold value based at least in part on adjusting the value of the second counter. In some examples, the die identification component 460 may be configured as or otherwise support a means for determining that a quantity of memory dies of the memory system that experience the charge loss at the higher rate than the one or more other memory dies satisfy a third threshold value. In some examples, the indication management component 440 may be configured as or otherwise support a means for refraining from storing the second indication based at least in part on determining that the quantity of memory dies that experience the charge loss at the higher rate than the one or more other memory dies satisfy the third threshold value.

In some examples, the testing operation component 455 may be configured as or otherwise support a means for performing, by testing circuitry associated with the memory system and prior to determining that the voltage characteristic of the first block of memory cells satisfies the first threshold value, a testing operation associated with each memory die of a plurality of memory dies of the memory system. In some examples, to perform the testing operation, the voltage monitoring component 425 may be configured as or otherwise support a means for determining whether each memory die of the plurality of memory dies experiences the charge loss at the higher rate than the one or more other memory dies based at least in part on applying a respective voltage to each memory die.

In some examples, storing the indication that the first memory die experiences charge loss at a higher rate than one or more other memory dies is based at least in part on a threshold quantity of blocks of memory cells of the first memory die including the voltage characteristic.

In some examples, determining that the voltage characteristic of the first block of memory cells satisfies the first threshold value is based at least in part on performing a first read operation. In some examples, the first read operation is associated with a first plurality of blocks of memory cells including at least the first block of memory cells. In some examples, each of the first plurality of blocks of memory cells are associated with a respective memory die of the memory system.

In some examples, the voltage monitoring component 425 may be configured as or otherwise support a means for determining that a voltage characteristic of a first block of memory cells satisfies a first threshold value. In some examples, the counter management component 430 may be configured as or otherwise support a means for adjusting a value of a counter associated with the first block based at least in part on determining that the voltage characteristic of the first block satisfies the first threshold value. In some examples, the counter comparison component 435 may be configured as or otherwise support a means for determining whether the value of the counter satisfies a second threshold value based at least in part on adjusting the value of the counter. In some examples, the indication management component 440 may be configured as or otherwise support a means for storing an indication that the first block experiences charge loss at a higher rate than one or more other blocks of memory cells based at least in part on the value of the counter satisfying the second threshold value.

In some examples, the voltage application component 445 may be configured as or otherwise support a means for applying a first read voltage to the first block of memory cells, where the voltage characteristic includes a voltage differential of the first block of memory cells based at least in part on applying the first read voltage to the first block of memory cells.

In some examples, the block selection component 450 may be configured as or otherwise support a means for refraining from selecting the first block of memory cells based at least in part on storing the indication that the first block experiences the charge loss at the higher rate than the one or more other blocks of memory cells. In some examples, the block selection component 450 may be configured as or otherwise support a means for selecting a second block of memory cells based at least in part on the second block not experiencing the charge loss at the higher rate than the first block of memory cells.

In some examples, the voltage monitoring component 425 may be configured as or otherwise support a means for determining that the voltage characteristic of a third block of memory cells satisfies the first threshold value. In some examples, the counter management component 430 may be configured as or otherwise support a means for adjusting a value of a third counter associated with the third block based at least in part on determining that the voltage characteristic of the third block satisfies the first threshold value. In some examples, the indication management component 440 may be configured as or otherwise support a means for refraining from storing a second indication that the third block experiences the charge loss at the higher rate than the one or more other blocks of memory cells based at least in part on the value of the third counter failing to satisfy the second threshold value.

In some examples, the voltage monitoring component 425 may be configured as or otherwise support a means for determining that the voltage characteristic of a fourth block of memory cells satisfies the first threshold value. In some examples, the counter management component 430 may be configured as or otherwise support a means for adjusting the value of a fourth counter based at least in part on determining that the voltage characteristic of the fourth block satisfies the first threshold value. In some examples, the counter management component 430 may be configured as or otherwise support a means for determining that the value of the fourth counter satisfies the second threshold value based at least in part on adjusting the value of the fourth counter. In some examples, the block identification component 465 may be configured as or otherwise support a means for determining that a quantity of blocks of memory cells of the memory system that experience the charge loss at the higher rate than the one or more other blocks of memory cells satisfy a third threshold value. In some examples, the indication management component 440 may be configured as or otherwise support a means for refraining from storing a third indication based at least in part on determining that the quantity of blocks of memory cells that experience the charge loss at the higher rate than the one or more other blocks of memory cells satisfy the third threshold value.

In some examples, the testing operation component 455 may be configured as or otherwise support a means for performing, by testing circuitry associated with the memory system and prior to determining that the voltage characteristic of the first block satisfies the first threshold value, a testing operation associated with each block of memory cells of a plurality of blocks of memory cells of the memory system. In some examples, to perform the testing operation, the voltage monitoring component 425 may be configured as or otherwise support a means for determining whether each block of memory cells of the plurality of blocks of memory cells experiences the charge loss at the higher rate than the one or more other blocks of memory cells based at least in part on applying a respective voltage to each block of memory cells.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

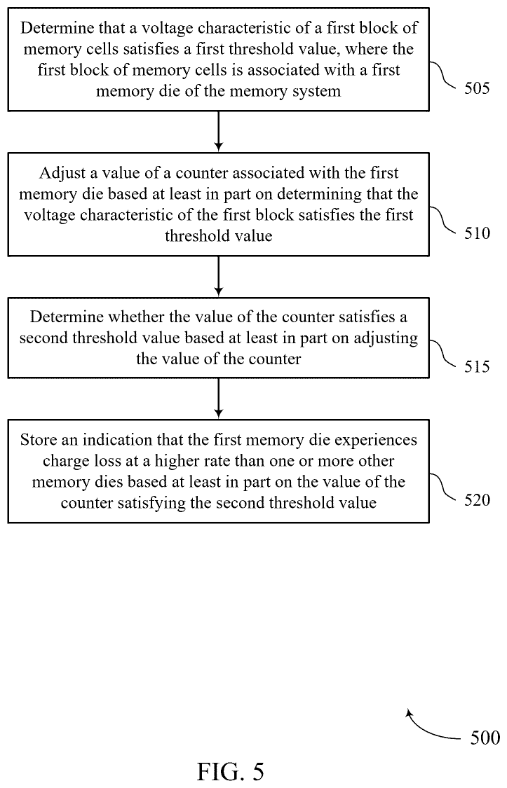

FIG. 5 shows a flowchart illustrating a method 500 that supports charge loss weak die identification in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include determining that a voltage characteristic of a first block of memory cells satisfies a first threshold value, where the first block of memory cells is associated with a first memory die of the memory system. In some examples, aspects of the operations of 505 may be performed by a voltage monitoring component 425 as described with reference to FIG. 4.

At 510, the method may include adjusting a value of a counter associated with the first memory die based at least in part on determining that the voltage characteristic of the first block satisfies the first threshold value. In some examples, aspects of the operations of 510 may be performed by a counter management component 430 as described with reference to FIG. 4.

At 515, the method may include determining whether the value of the counter satisfies a second threshold value based at least in part on adjusting the value of the counter. In some examples, aspects of the operations of 515 may be performed by a counter comparison component 435 as described with reference to FIG. 4.

At 520, the method may include storing an indication that the first memory die experiences charge loss at a higher rate than one or more other memory dies based at least in part on the value of the counter satisfying the second threshold value. In some examples, aspects of the operations of 520 may be performed by an indication management component 440 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for determining that a voltage characteristic of a first block of memory cells satisfies a first threshold value, where the first block of memory cells is associated with a first memory die of the memory system; adjusting a value of a counter associated with the first memory die based at least in part on determining that the voltage characteristic of the first block satisfies the first threshold value; determining whether the value of the counter satisfies a second threshold value based at least in part on adjusting the value of the counter; and storing an indication that the first memory die experiences charge loss at a higher rate than one or more other memory dies based at least in part on the value of the counter satisfying the second threshold value.

Aspect 2: The method, apparatus, or non-transitory computer-readable medium of aspect 1, further including operations, features, circuitry, logic, means, or instructions, or any combination thereof for applying a first read voltage to the first block of memory cells, where the voltage characteristic includes a voltage differential of the first block of memory cells based at least in part on applying the first read voltage to the first block of memory cells.

Aspect 3: The method, apparatus, or non-transitory computer-readable medium of any of aspects 1 through 2, further including operations, features, circuitry, logic, means, or instructions, or any combination thereof for determining, prior to determining that the voltage characteristic of the first block of memory cells satisfies the first threshold value, that the voltage characteristic of a second block of memory cells satisfies the first threshold value, where the second block of memory cells is associated with the first memory die; adjusting the value of the counter associated with the first memory die based at least in part on determining that the voltage characteristic of the second block satisfies the first threshold value; determining whether the value of the counter satisfies a second threshold value based at least in part on adjusting the value of the counter; and refraining from storing the indication that the first memory die experiences the charge loss at the higher rate than the one or more other memory dies based at least in part on the value of the counter failing to satisfy the second threshold value.

Aspect 4: The method, apparatus, or non-transitory computer-readable medium of any of aspects 1 through 3, further including operations, features, circuitry, logic, means, or instructions, or any combination thereof for selecting a block of memory cells from a plurality of blocks of memory cells, where selecting the block of memory cells includes: refraining from selecting a third block of memory cells of the plurality of blocks of memory cells that is associated with the first memory die based at least in part on storing the indication that the first memory die experiences the charge loss at the higher rate than the one or more other memory dies; and selecting a fourth block of memory cells of the plurality of blocks of memory cells that is associated with a second memory die based at least in part on the second memory die not experiencing the charge loss at the higher rate than the one or more other memory dies.

Aspect 5: The method, apparatus, or non-transitory computer-readable medium of any of aspects 1 through 4, further including operations, features, circuitry, logic, means, or instructions, or any combination thereof for determining that the voltage characteristic of a fourth block of memory cells satisfies the first threshold value, where the fourth block of memory cells is associated with a second memory die of the memory system; adjusting a value of a second counter associated with the second memory die based at least in part on determining that the voltage characteristic of the fourth block satisfies the first threshold value; and refraining from storing a second indication that the second memory die experiences the charge loss at the higher rate than the one or more other memory dies based at least in part on the value of the second counter failing to satisfy the second threshold value.

Aspect 6: The method, apparatus, or non-transitory computer-readable medium of aspect 5, further including operations, features, circuitry, logic, means, or instructions, or any combination thereof for determining that the voltage characteristic of a fifth block of memory cells satisfies the first threshold value, where the fifth block of memory cells is associated with the second memory die; adjusting the value of the second counter based at least in part on determining that the voltage characteristic of the fifth block satisfies the first threshold value; determining that the value of the second counter satisfies the second threshold value based at least in part on adjusting the value of the second counter; determining that a quantity of memory dies of the memory system that experience the charge loss at the higher rate than the one or more other memory dies satisfy a third threshold value; and refraining from storing the second indication based at least in part on determining that the quantity of memory dies that experience the charge loss at the higher rate than the one or more other memory dies satisfy the third threshold value.

Aspect 7: The method, apparatus, or non-transitory computer-readable medium of any of aspects 1 through 6, further including operations, features, circuitry, logic, means, or instructions, or any combination thereof for performing, by testing circuitry associated with the memory system and prior to determining that the voltage characteristic of the first block of memory cells satisfies the first threshold value, a testing operation associated with each memory die of a plurality of memory dies of the memory system, where performing the testing operation includes determining whether each memory die of the plurality of memory dies experiences the charge loss at the higher rate than the one or more other memory dies based at least in part on applying a respective voltage to each memory die.

Aspect 8: The method, apparatus, or non-transitory computer-readable medium of any of aspects 1 through 7, where storing the indication that the first memory die experiences charge loss at a higher rate than one or more other memory dies is based at least in part on a threshold quantity of blocks of memory cells of the first memory die including the voltage characteristic.

Aspect 9: The method, apparatus, or non-transitory computer-readable medium of any of aspects 1 through 8, where determining that the voltage characteristic of the first block of memory cells satisfies the first threshold value is based at least in part on performing a first read operation; the first read operation is associated with a first plurality of blocks of memory cells including at least the first block of memory cells; and each of the first plurality of blocks of memory cells are associated with a respective memory die of the memory system.

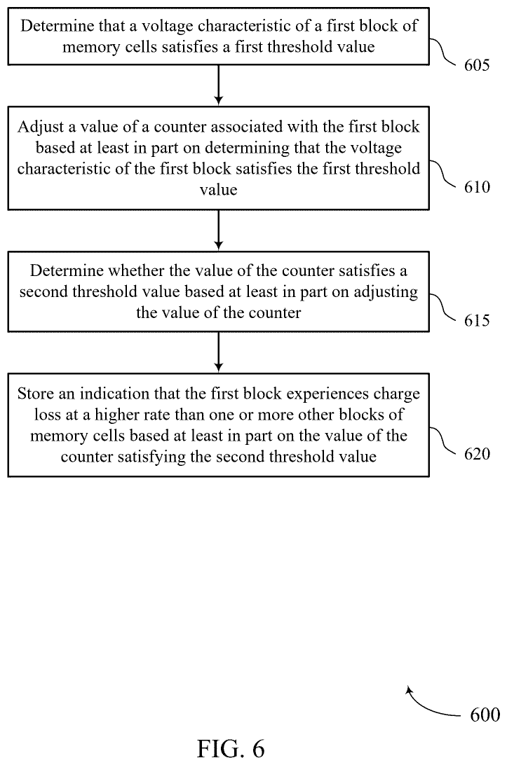

FIG. 6 shows a flowchart illustrating a method 600 that supports charge loss weak die identification in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include determining that a voltage characteristic of a first block of memory cells satisfies a first threshold value. In some examples, aspects of the operations of 605 may be performed by a voltage monitoring component 425 as described with reference to FIG. 4.

At 610, the method may include adjusting a value of a counter associated with the first block based at least in part on determining that the voltage characteristic of the first block satisfies the first threshold value. In some examples, aspects of the operations of 610 may be performed by a counter management component 430 as described with reference to FIG. 4.

At 615, the method may include determining whether the value of the counter satisfies a second threshold value based at least in part on adjusting the value of the counter.

In some examples, aspects of the operations of 615 may be performed by a counter comparison component 435 as described with reference to FIG. 4.

At 620, the method may include storing an indication that the first block experiences charge loss at a higher rate than one or more other blocks of memory cells based at least in part on the value of the counter satisfying the second threshold value. In some examples, aspects of the operations of 620 may be performed by an indication management component 440 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 10: A method, apparatus, or non-transitory computer-readable medium including operations, features, circuitry, logic, means, or instructions, or any combination thereof for determining that a voltage characteristic of a first block of memory cells satisfies a first threshold value; adjusting a value of a counter associated with the first block based at least in part on determining that the voltage characteristic of the first block satisfies the first threshold value; determining whether the value of the counter satisfies a second threshold value based at least in part on adjusting the value of the counter; and storing an indication that the first block experiences charge loss at a higher rate than one or more other blocks of memory cells based at least in part on the value of the counter satisfying the second threshold value.

Aspect 11: The method, apparatus, or non-transitory computer-readable medium of aspect 10, further including operations, features, circuitry, logic, means, or instructions, or any combination thereof for applying a first read voltage to the first block of memory cells, where the voltage characteristic includes a voltage differential of the first block of memory cells based at least in part on applying the first read voltage to the first block of memory cells.

Aspect 12: The method, apparatus, or non-transitory computer-readable medium of any of aspects 10 through 11, further including operations, features, circuitry, logic, means, or instructions, or any combination thereof for refraining from selecting the first block of memory cells based at least in part on storing the indication that the first block experiences the charge loss at the higher rate than the one or more other blocks of memory cells and selecting a second block of memory cells based at least in part on the second block not experiencing the charge loss at the higher rate than the first block of memory cells.

Aspect 13: The method, apparatus, or non-transitory computer-readable medium of any of aspects 10 through 12, further including operations, features, circuitry, logic, means, or instructions, or any combination thereof for determining that the voltage characteristic of a third block of memory cells satisfies the first threshold value; adjusting a value of a third counter associated with the third block based at least in part on determining that the voltage characteristic of the third block satisfies the first threshold value; and refraining from storing a second indication that the third block experiences the charge loss at the higher rate than the one or more other blocks of memory cells based at least in part on the value of the third counter failing to satisfy the second threshold value.

Aspect 14: The method, apparatus, or non-transitory computer-readable medium of aspect 13, further including operations, features, circuitry, logic, means, or instructions, or any combination thereof for determining that the voltage characteristic of a fourth block of memory cells satisfies the first threshold value; adjusting the value of a fourth counter based at least in part on determining that the voltage characteristic of the fourth block satisfies the first threshold value; determining that the value of the fourth counter satisfies the second threshold value based at least in part on adjusting the value of the fourth counter; determining that a quantity of blocks of memory cells of the memory system that experience the charge loss at the higher rate than the one or more other blocks of memory cells satisfy a third threshold value; and refraining from storing a third indication based at least in part on determining that the quantity of blocks of memory cells that experience the charge loss at the higher rate than the one or more other blocks of memory cells satisfy the third threshold value.

Aspect 15: The method, apparatus, or non-transitory computer-readable medium of any of aspects 10 through 14, further including operations, features, circuitry, logic, means, or instructions, or any combination thereof for performing, by testing circuitry associated with the memory system and prior to determining that the voltage characteristic of the first block satisfies the first threshold value, a testing operation associated with each block of memory cells of a plurality of blocks of memory cells of the memory system, where performing the testing operation includes determining whether each block of memory cells of the plurality of blocks of memory cells experiences the charge loss at the higher rate than the one or more other blocks of memory cells based at least in part on applying a respective voltage to each block of memory cells.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method by a memory system, comprising:
determining that a voltage characteristic of a first block of memory cells satisfies a first threshold value, wherein the first block of memory cells is associated with a first memory die of the memory system;
adjusting a value of a counter associated with the first memory die based at least in part on determining that the voltage characteristic of the first block satisfies the first threshold value;
determining whether the value of the counter satisfies a second threshold value based at least in part on adjusting the value of the counter; and
storing an indication that the first memory die experiences charge loss at a higher rate than one or more other memory dies based at least in part on the value of the counter satisfying the second threshold value.

2. The method of claim 1, further comprising:
applying a first read voltage to the first block of memory cells, wherein the voltage characteristic comprises a voltage differential of the first block of memory cells based at least in part on applying the first read voltage to the first block of memory cells.

3. The method of claim 1, further comprising:
determining, prior to determining that the voltage characteristic of the first block of memory cells satisfies the first threshold value, that the voltage characteristic of a second block of memory cells satisfies the first threshold value, wherein the second block of memory cells is associated with the first memory die;
adjusting the value of the counter associated with the first memory die based at least in part on determining that the voltage characteristic of the second block satisfies the first threshold value;
determining whether the value of the counter satisfies the second threshold value based at least in part on adjusting the value of the counter; and
refraining from storing the indication that the first memory die experiences the charge loss at the higher rate than the one or more other memory dies based at least in part on the value of the counter failing to satisfy the second threshold value.

4. The method of claim 1, further comprising:
selecting a block of memory cells from a plurality of blocks of memory cells, wherein selecting the block of memory cells comprises:
refraining from selecting a third block of memory cells of the plurality of blocks of memory cells that is associated with the first memory die based at least in part on storing the indication that the first memory die experiences the charge loss at the higher rate than the one or more other memory dies; and
selecting a fourth block of memory cells of the plurality of blocks of memory cells that is associated with a second memory die based at least in part on the second memory die not experiencing the charge loss at the higher rate than the one or more other memory dies.

5. The method of claim 1, further comprising:
determining that the voltage characteristic of a fourth block of memory cells satisfies the first threshold value, wherein the fourth block of memory cells is associated with a second memory die of the memory system;
adjusting a value of a second counter associated with the second memory die based at least in part on determining that the voltage characteristic of the fourth block satisfies the first threshold value; and
refraining from storing a second indication that the second memory die experiences the charge loss at the higher rate than the one or more other memory dies based at least in part on the value of the second counter failing to satisfy the second threshold value.

6. The method of claim 5, further comprising:
determining that the voltage characteristic of a fifth block of memory cells satisfies the first threshold value, wherein the fifth block of memory cells is associated with the second memory die;
adjusting the value of the second counter based at least in part on determining that the voltage characteristic of the fifth block satisfies the first threshold value;
determining that the value of the second counter satisfies the second threshold value based at least in part on adjusting the value of the second counter;
determining that a quantity of memory dies of the memory system that experience the charge loss at the higher rate than the one or more other memory dies satisfy a third threshold value; and
refraining from storing the second indication based at least in part on determining that the quantity of memory dies that experience the charge loss at the higher rate than the one or more other memory dies satisfy the third threshold value.

7. The method of claim 1, further comprising:
performing, by testing circuitry associated with the memory system and prior to determining that the voltage characteristic of the first block of memory cells satisfies the first threshold value, a testing operation associated with each memory die of a plurality of memory dies of the memory system, wherein performing the testing operation comprises:
determining whether each memory die of the plurality of memory dies experiences the charge loss at the higher rate than the one or more other memory dies based at least in part on applying a respective voltage to each memory die.

8. The method of claim 1, wherein storing the indication that the first memory die experiences the charge loss at the higher rate than the one or more other memory dies is based at least in part on a threshold quantity of blocks of memory cells of the first memory die comprising the voltage characteristic.

9. The method of claim 1, wherein determining that the voltage characteristic of the first block of memory cells satisfies the first threshold value is based at least in part on performing a first read operation, the first read operation is associated with a first plurality of blocks of memory cells comprising at least the first block of memory cells, and each of the first plurality of blocks of memory cells are associated with a respective memory die of the memory system.

10. A method by a memory system, comprising:
determining that a voltage characteristic of a first block of memory cells satisfies a first threshold value;
adjusting a value of a counter associated with the first block based at least in part on determining that the voltage characteristic of the first block satisfies the first threshold value;
determining whether the value of the counter satisfies a second threshold value based at least in part on adjusting the value of the counter; and
storing an indication that the first block experiences charge loss at a higher rate than one or more other blocks of memory cells based at least in part on the value of the counter satisfying the second threshold value.

11. The method of claim 10, further comprising:
applying a first read voltage to the first block of memory cells, wherein the voltage characteristic comprises a voltage differential of the first block of memory cells based at least in part on applying the first read voltage to the first block of memory cells.

12. The method of claim 10, further comprising:
refraining from selecting the first block of memory cells based at least in part on storing the indication that the first block experiences the charge loss at the higher rate than the one or more other blocks of memory cells; and
selecting a second block of memory cells based at least in part on the second block not experiencing the charge loss at the higher rate than the first block of memory cells.

13. The method of claim 10, further comprising:
determining that the voltage characteristic of a third block of memory cells satisfies the first threshold value;
adjusting a value of a third counter associated with the third block based at least in part on determining that the voltage characteristic of the third block satisfies the first threshold value; and
refraining from storing a second indication that the third block experiences the charge loss at the higher rate than the one or more other blocks of memory cells based at least in part on the value of the third counter failing to satisfy the second threshold value.

14. The method of claim 13, further comprising:
determining that the voltage characteristic of a fourth block of memory cells satisfies the first threshold value;
adjusting a value of a fourth counter based at least in part on determining that the voltage characteristic of the fourth block satisfies the first threshold value;
determining that the value of the fourth counter satisfies the second threshold value based at least in part on adjusting the value of the fourth counter;
determining that a quantity of blocks of memory cells of the memory system that experience the charge loss at the higher rate than the one or more other blocks of memory cells satisfy a third threshold value; and
refraining from storing a third indication based at least in part on determining that the quantity of blocks of memory cells that experience the charge loss at the higher rate than the one or more other blocks of memory cells satisfy the third threshold value.

15. The method of claim 10, further comprising:
performing, by testing circuitry associated with the memory system and prior to determining that the voltage characteristic of the first block satisfies the first threshold value, a testing operation associated with each block of memory cells of a plurality of blocks of memory cells of the memory system, wherein performing the testing operation comprises:
determining whether each block of memory cells of the plurality of blocks of memory cells experiences the charge loss at the higher rate than the one or more other blocks of memory cells based at least in part on applying a respective voltage to each block of memory cells.

16. A memory system, comprising:
one or more memory devices; and
processing circuitry coupled with the one or more memory devices and configured to cause the memory system to:
determine that a voltage characteristic of a first block of memory cells satisfies a first threshold value, wherein the first block of memory cells is associated with a first memory die of the memory system;
adjust a value of a counter associated with the first memory die based at least in part on determining that the voltage characteristic of the first block satisfies the first threshold value;
determine whether the value of the counter satisfies a second threshold value based at least in part on adjusting the value of the counter; and
store an indication that the first memory die experiences charge loss at a higher rate than one or more other memory dies based at least in part on the value of the counter satisfying the second threshold value.

17. The memory system of claim 16, wherein the processing circuitry is further configured to cause the memory system to:
apply a first read voltage to the first block of memory cells, wherein the voltage characteristic comprises a voltage differential of the first block of memory cells based at least in part on applying the first read voltage to the first block of memory cells.

18. The memory system of claim 16, wherein the processing circuitry is further configured to cause the memory system to:
determine, prior to determining that the voltage characteristic of the first block of memory cells satisfies the first threshold value, that the voltage characteristic of a second block of memory cells satisfies the first threshold value, wherein the second block of memory cells is associated with the first memory die;
adjust the value of the counter associated with the first memory die based at least in part on determining that the voltage characteristic of the second block satisfies the first threshold value;
determine whether the value of the counter satisfies the second threshold value based at least in part on adjusting the value of the counter; and
refrain from storing the indication that the first memory die experiences the charge loss at the higher rate than the one or more other memory dies based at least in part on the value of the counter failing to satisfy the second threshold value.

19. The memory system of claim 16, wherein the processing circuitry is further configured to cause the memory system to:
select a block of memory cells from a plurality of blocks of memory cells, wherein, to select the block of memory cells, the processing circuitry is configured to:
refrain from selecting a third block of memory cells of the plurality of blocks of memory cells that is associated with the first memory die based at least in part on storing the indication that the first memory die experiences the charge loss at the higher rate than the one or more other memory dies; and
select a fourth block of memory cells of the plurality of blocks of memory cells that is associated with a second memory die based at least in part on the second memory die not experiencing the charge loss at the higher rate than the one or more other memory dies.

20. The memory system of claim 16, wherein the processing circuitry is further configured to cause the memory system to:
determine that the voltage characteristic of a fourth block of memory cells satisfies the first threshold value, wherein the fourth block of memory cells is associated with a second memory die of the memory system;
adjust a value of a second counter associated with the second memory die based at least in part on determining that the voltage characteristic of the fourth block satisfies the first threshold value; and
refrain from storing a second indication that the second memory die experiences the charge loss at the higher rate than the one or more other memory dies based at least in part on the value of the second counter failing to satisfy the second threshold value.

21. The memory system of claim 20, wherein the processing circuitry is further configured to cause the memory system to:
determine that the voltage characteristic of a fifth block of memory cells satisfies the first threshold value, wherein the fifth block of memory cells is associated with the second memory die;
adjust the value of the second counter based at least in part on determining that the voltage characteristic of the fifth block satisfies the first threshold value;
determine that the value of the second counter satisfies the second threshold value based at least in part on adjusting the value of the second counter;
determine that a quantity of memory dies of the memory system that experience the charge loss at the higher rate than the one or more other memory dies satisfy a third threshold value; and
refrain from storing the second indication based at least in part on determining that the quantity of memory dies that experience the charge loss at the higher rate than the one or more other memory dies satisfy the third threshold value.

22. The memory system of claim 16, wherein the processing circuitry is further configured to cause the memory system to:
perform, by testing circuitry associated with the memory system and prior to determining that the voltage characteristic of the first block of memory cells satisfies the first threshold value, a testing operation associated with each memory die of a plurality of memory dies of the memory system, and wherein, to perform the testing operation, the processing circuitry is configured to:
determine whether each memory die of the plurality of memory dies experiences the charge loss at the higher rate than the one or more other memory dies based at least in part on applying a respective voltage to each memory die.

23. The memory system of claim 16, wherein storing the indication that the first memory die experiences the charge loss at the higher rate than the one or more other memory dies is based at least in part on a threshold quantity of blocks of memory cells of the first memory die comprising the voltage characteristic.

24. A memory system, comprising:
one or more memory devices; and
processing circuitry coupled with the one or more memory devices and configured to cause the memory system to:
determine that a voltage characteristic of a first block of memory cells satisfies a first threshold value;
adjust a value of a counter associated with the first block based at least in part on determining that the voltage characteristic of the first block satisfies the first threshold value;
determine whether the value of the counter satisfies a second threshold value based at least in part on adjusting the value of the counter; and
store an indication that the first block experiences charge loss at a higher rate than one or more other blocks of memory cells based at least in part on the value of the counter satisfying the second threshold value.

25. The memory system of claim 24, wherein the processing circuitry is further configured to cause the memory system to:
apply a first read voltage to the first block of memory cells, wherein the voltage characteristic comprises a voltage differential of the first block of memory cells based at least in part on applying the first read voltage to the first block of memory cells.
